(19) United States
(12) Patent Application Publication
(10) Pub. No.: US 2010/0164030 A1
(43) Pub. Date: Jul. 1, 2010

(54) CHIP CARRIER BEARING LARGE SILICON FOR HIGH PERFORMANCE COMPUTING AND RELATED METHOD

(75) Inventors: Stefano S. Oggioni, Milano (IT); Edmund D. Blackshear, Wappingers Falls, NY (US); Claudius Feger, Poughkeepsie, NY (US)

Correspondence Address: CAREY, RODRIGUEZ, GREENBERG & PAUL, LLP;STEVEN M. GREENBERG, 950 PENINSULA CORPORATE CIRCLE, SUITE 2022, BOCA RATON, FL, 33487, US

(73) Assignee: INTERNATIONAL BUSINESS MACHINES CORPORATION, Armonk, NY (US)

(21) Appl. No.: 12/347,490

(22) Filed: Dec. 31, 2008

(51) Int. Cl. H01L 23/08; H01L 31/0232; H01L 21/71

(52) U.S. Cl. 257/432; 257/729; 438/121; 438/27; 438/118; 257/E23.192; 257/E31.127; 257/433; 257/E21.536

(57) ABSTRACT

Embodiments of the present invention provide a system and method for manufacturing integrated circuit (IC) chip packages. In one embodiment, the integrated circuit (IC) chip package can include an IC chip and a substrate coupled to the IC chip. The substrate can include a glass fiber re-enforced epoxy core, a plurality copper circuitry containing particle re-enforced epoxy layers symmetrically-oriented to each surface of the glass fiber re-enforced epoxy core, and an outermost amorphous glass layer on each surface of the plurality of layers. The IC chip can be coupled to copper circuitry bonded to one of the outermost amorphous glass layers.

### BACKGROUND OF THE INVENTION

1. Statement of the Technical Field

The present invention relates to integrated circuit (IC) chip packages and more particularly to IC chip packages having outermost amorphous glass foil layers.

2. Description of the Related Art

The current trend in the industry is to grow technology in the direction of becoming capable to host large die mounted on organic carriers. These chip carriers are based on the evolution of printed circuit boards, which started to add layers, with improved capability in the definition of wiring features, by a sequential process.

The advantages of the new technology were mainly achieved by no longer using the lamination of glass reinforced material sheets but adding layers, made of pure resin, coated with a patterned copper metallization layer. The industry continues to evolve this sequential layering technology by adding more and more layers to a point that eight (8) layers per side (to maintain symmetry) are being prototyped and roadmaps start to predict ten (10) to twelve (12) layers. Concurrently, the complexity of semiconductor devices continues to grow at a faster rate than what the substrate technology signifies it will be able to handle. From the basic lack of common speed in achieving the same order of magnitude of miniaturization occurring between different generations of silicon, the substrate technologist is forced to grow the number of layers. Currently, the increase in the number of layers of the substrate is the only direct process to achieve the overall density required to provide all the connections present at chip level.

Although the technique of adding layers made of resin (loaded with very small particles of Silica fillers), over a rigid base of glass reinforced copper cladded composite material, similar to the technique used for a printed circuit board (PCB), has delivered the necessary results, this technique has started to show the limits of the technology. One observed limiting factor of the current technique is meeting the required “flatness” or “levelness” for these plastic substrates in order to provide an appropriate mating with a significantly flat semiconductor die chip. Deviations in the flatness of the two mating surfaces can result in a difficult process during the joining or connecting of the plastic substrate and the semiconductor chip. At the semiconductor level, there are small bumps of soldering alloys or metals that assist to a degree in overcoming the non-flat mating surfaces. In addition, in order to keep pace with the increased number of gates being placed into a single device, the semiconductor chips are undergoing a great process of miniaturization. With miniaturization, the capacity of the technique of adding layers made of resin loaded with silica fillers to mitigate disparity of flatness diminishes substantially.

The ever-increasing density of the connections requirement applies a further worsening factor in the construction of the laminate. Analogously to the growing density of interconnections—chip to carrier, the same ever-increasing density must be managed within the carrier layers and structures, but not only in a two-dimensional relation of connections per squared millimeter (mm²). As chip modules are three-dimensional structures, the ever-increasing density of the connections requirement translates into the necessity of greater density of vertical paths across the central portion of these laminate. The higher density of plated holes requires that the aspect ratio of the holes remain within specific limits. The drill diameter and the length of the hole to be plated define the aspect ratio within which the process can deliver products at reasonable cost. To increase the density of holes per mm², the current trend is to reduce the diameter of the holes. Since the aspect ratio is a defined maximum value, the thickness of the substrate rigid portion (called Core) has been and continues to be the one variable that is changed. A thinner core and a growing number of sequentially added resin layers has now reached a point where coefficient of thermal expansion (CTE), different shrinking factor in the polymers curing, and design specific characteristics combine to create conditions that result in warped substrates. The warping of substrates becomes a more relevant factor as it limits the size of the silicon chip that can be mounted on top of these substrates.

Currently in the PCB and IC chip carrier and/or package industry, there is the concept of attaching on the top and on the bottom of the stack of resin layers (the ones added sequentially) foils of rigid glass cloth materials. These foils of rigid glass cloth materials are the same as the foils that are used in standard PCB construction and in building the central section (the core) of these substrates. Unfortunately, the first sets of experiments have revealed another limiting factor that is driven by the presence of the fibers of the glass cloth. In general, the fibers of the glass cloth have shown two failure mechanisms. Due to the high density minimum pitch of the semiconductor chip (currently at 200 microns and progressing to 150 microns or even lower), the laser drill process leaves exposed protruding glass fibers in the newly created holes. These protruding glass fibers in the holes cause plating defects that are becoming critical to withstand stress conditions.

In a different, yet related failure mechanism, and after the completion of all the plating process and power up of the device, these same protruding fibers (or simply the fibers present in the glass cloth) are exposed to an electrical bias that facilitates metal migration between two ends of the same fibers to cause electrical shorts. This kind of defect is commonly referred to as Conductive Anodic Filament (CAF). CAF is a well-known problem for standard PCBs, which have significantly lower density of structures than IC chip packages/carriers.

In addition, the added layers of foils made of electrical-grade glass cloths impregnated with resins are a composite material. The behavior of the added layers of foils with respect to temperature variations is determined by their composition. This behavior is based on the type of glass cloth and the quantity of resin used in the formation of the composite. As previously mentioned, one of the most critical aspects is the difference of the coefficient of thermal expansion (CTE) between the laminates and the semiconductor devices. CTE mismatch can be exacerbated by a particular phenomenon typically referred to as the temperature of glass transition (Tg), which increases the thermal expansion of the composite material when it goes above specific temperatures. As illustrated in FIG. 1, composite materials behave differently at different temperature ranges, e.g., α₁ and α₂, where α₁ is generally indicated as below Tg and α₂ is generally indicated as above Tg temperature. The CTE of the composite materials are driven by specific or combined properties of the different materials used to produce the composites.

In a conventional PCB composite material, it is common knowledge that the for those temperatures below α₁, the CTE of the composite material will mostly be controlled by the glassy state of the resin complex having the greatest number of chemical bonds still intact, as well as by the properties of the glass making process and the properties of the cloth (i.e. warp over fill ratio). Resins expand isotropically with temperature (e.g., from 60-200 ppm° C.) and typically drive the Z-axis expansion in the composite. In contrast, the glass cloth (with warp and fill non uniformity) will drive most of the composite expansion properties in X-axis and Y-axis directions (e.g., 16-26 ppm° C.).

At temperatures above Tg (e.g., α₂), the resin can undergo a greater mobility, due to thermal fluctuation that breaks chemical bonds to facilitate the flow of material, and greater isotropic expansion that generally becomes increasingly predominant with the increase of temperature also in the X-axis and Y-axis direction (this is true within the temperature range of interest for PCB and organic chip carriers up to 300° C.). These composite materials present this non-linear behavior in the temperature range of interest during semiconductor bonding. In particular, the bonding operation is performed well above resin/composite Tg temperatures while operational life of the product, as well as storage of parts, is generally performed at temperatures which are well below Tg.

Furthermore, the non-linear behavior of the material expansion can affect the assembly yields, which require 100% joint formation for semiconductors, as well as the reliability of formed joints. For example, stresses are formed within the joints as the relative position and/or distance of each individual joint from the central neutral point of the chip-substrate system is changed by temperature, e.g., room temperature, soldering joints temperature and alloy solidification temperature—which immobilizes the joint between semiconductor and substrate. The aforementioned changes to the relative joint positions with respect to the central neutral point of the (thermo)mechanical system can deliver increasing levels of embedded stresses, e.g., shear, compressive and or tensile in different areas of a large semiconductor device, which can limit the life of the product. Composite materials, e.g., cloths, present gaps between warp and fill of the texture, the gaps represent a limitation in the uniformity of composite material construction that is becoming a more representative ratio when compared to the required geometries being pursued by the microelectronic interconnection densities per unit of area.

### SUMMARY OF THE INVENTION

Embodiments of the present invention address deficiencies of the art in respect to integrated circuit (IC) chip packages and provide a novel and non-obvious system and method for manufacturing IC chip packages. In an embodiment of the invention, an IC chip package can be provided. The integrated circuit (IC) chip package can include an IC chip and a substrate coupled to the IC chip. The substrate can include a glass fiber re-enforced epoxy core, a plurality copper circuitry containing a plurality of particle re-enforced epoxy layers symmetrically-oriented to each surface of the glass fiber re-enforced epoxy core, and an outermost amorphous glass layer on each surface of the plurality of layers. The IC chip can be coupled to copper circuitry bonded to one of the outermost amorphous glass layers.

In one aspect of the embodiment, the glass layer can be one of chemical resistant glass (C-Glass), high-alkali glass (A-Glass), electrical grade glass (E-Glass), high-strength glass (S-Glass) and dielectric constant glass (D-Glass). In another aspect of the embodiment, the glass layer can be optical glass. In yet another aspect of the embodiment, the outermost amorphous glass layer can be formed separately from the plurality of layers. The outermost amorphous glass layer can be pre-cured and perforated with a desired connection pattern prior to bonding with the plurality of layers.

In embodiment of the invention, a method for manufacturing integrated circuit (IC) chip packages is provided. The method for manufacturing integrated circuit (IC) chip packages can include forming a glass fiber re-enforced epoxy core, forming a plurality copper circuitry that contain particle re-enforced epoxy layers symmetrically to each surface of the glass fiber re-enforced epoxy core, forming an outermost amorphous glass layer on each surface of the plurality of layers and mounting an IC chip to copper circuitry bonded to one of the outermost amorphous glass layers.

In one aspect of the embodiment, forming an outermost amorphous glass layer can include pre-curing the outermost layer and bonding the outermost layer to the plurality of layers using pressure, heat and an adhesive layer. In another aspect of the embodiment, forming an outermost amorphous glass layer can include pre-curing the outermost amorphous glass layer and perforating the outermost amorphous glass layer with a desired connection pattern.

Additional aspects of the invention will be set forth in part in the description which follows, and in part will be obvious from the description, or may be learned by practice of the invention. The aspects of the invention will be realized and attained by means of the elements and combinations particularly pointed out in the appended claims. It is to be understood that both the foregoing general description and the following detailed description are exemplary and explanatory only and are not restrictive of the invention, as claimed.

### BRIEF DESCRIPTION OF THE SEVERAL VIEWS OF THE DRAWINGS

The accompanying drawings, which are incorporated in and constitute part of this specification, illustrate embodiments of the invention and together with the description, serve to explain the principles of the invention. The embodiments illustrated herein are presently preferred, it being understood, however, that the invention is not limited to the precise arrangements and instrumentalities shown, wherein:

FIG. 1 is a diagram illustrating a temperature of glass transition Tg with respect to a coefficient of thermal expansion (CTE) and temperature;

FIG. 2 is a cross-sectional view of an IC chip package that is constructed in accordance with an embodiment of the present invention; and,

FIG. 3 is a flowchart illustrating a process for manufacturing IC chip packages in accordance with an embodiment of the present invention.

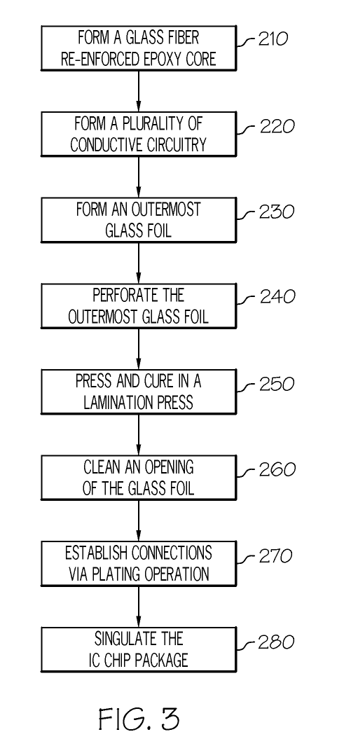

### DETAILED DESCRIPTION OF THE INVENTION

Embodiments of the present invention address deficiencies of the art in respect to IC chip packages and provide a novel and non-obvious apparatus and method for manufacturing IC chip packages. In accordance with an embodiment of the present invention, IC chip packages can be provided. The IC chip packages can include an IC chip and a substrate coupled to the IC chip. The substrate can include a glass fiber re-enforced epoxy core, a plurality of copper circuitry containing, particle re-enforced epoxy layers symmetrically-oriented to each surface of the core and an outermost glass layer or foil on each surface of the plurality of layers. The outermost glass layer or foil can be pre-cured, e.g., away from the plurality of layers, and then bonded to symmetrical particle re-enforced epoxy layers using pressure, heat and an adhesive layer.

In accordance with another embodiment of the present invention, a method for providing chip carriers is provided. The method for providing chip carriers can include forming a glass fiber re-enforced epoxy core, forming a plurality of copper circuitry, which contain particle re-enforced epoxy layers symmetrically-oriented to each surface of the glass fiber re-enforced epoxy core and forming an outermost amorphous electrical grade glass (E-Glass) layer or foil on each surface of the plurality of layers. The method further can include mounting an IC chip to copper circuitry bonded to one of the outermost amorphous glass layers or foils. In one aspect of the embodiment, the glass layer can be one of chemical resistant glass (C-Glass), high-alkali glass (A-Glass), electrical grade glass (E-Glass), high-strength glass (S-Glass) and dielectric constant glass (D-Glass). In another aspect of the embodiment, the glass layer can be optical glass. In embodiments, the outermost amorphous glass foil can be formed separately from the plurality of layers, pre-cured and then perforated with a desired connection pattern. The perforated glass foil can be bonded to the plurality of layers using pressure, heat and an adhesive layer.

When joining large semiconductors to substrates, the use of an amorphous glass layer can compensate for the problems of the greater CTE when composite materials are processed at temperatures exceeding their “composite” glass transition (Tg) temperature. Amorphous glass foils, as well as any other glasses, will still have a Tg temperature; however, the temperature of glass transition for the amorphous glass will be at much higher temperatures than the temperature of glass transition of conventional glass cloth composite materials. In general, the temperature of glass transition for most glasses are outside of the range of temperatures that are of interest for the microelectronic interconnection over organic carriers, as well as above the decomposition temperatures of most polymers used in electronics.

In addition, the combination of required temperatures ranges to achieve soldering, which for the amorphous glass foil will be below the temperature of glass transition, provide for the bonding process to work within the required range of temperatures with a known and more predictable material behavior such as CTE linearity. Moreover, the use an amorphous glass material foil, which can include engineered CTE properties, can enable the joining of very large semiconductors to substrates.

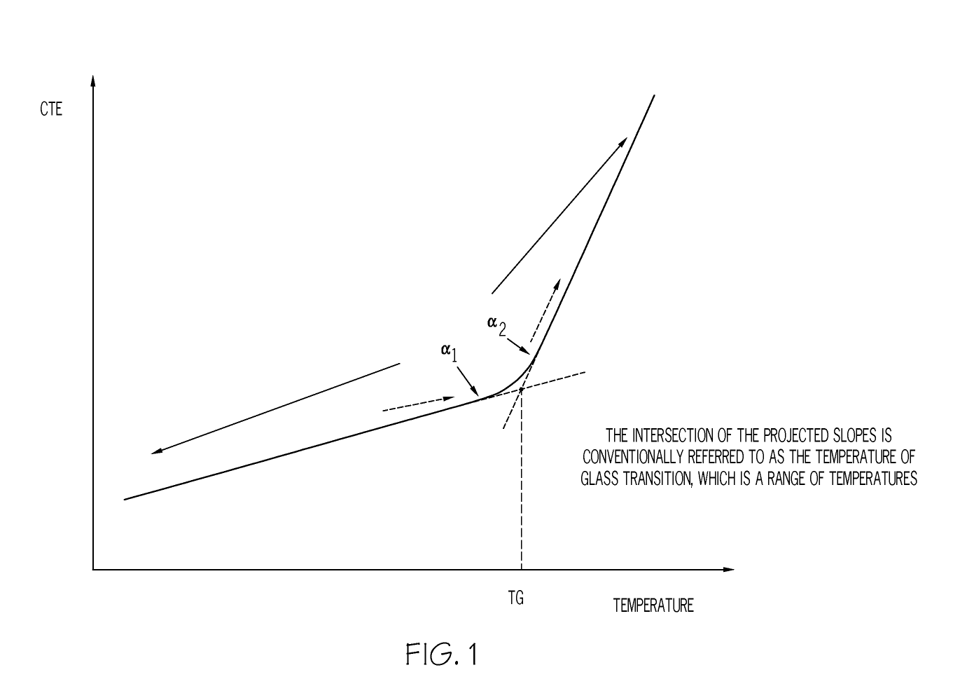

In illustration, FIG. 1 is a cross-sectional view of one embodiment of an integrated circuit (IC) chip package. The IC chip package 100 can include an IC chip 102 and a substrate 104 coupled to IC chip 102. Substrate 104 can include a glass fiber re-enforced epoxy core 106, a plurality of copper circuitry 108 containing, particle re-enforced epoxy layers 110 symmetrically-oriented to each surface 112, 116 of core 106. In embodiments, an outermost glass layer or foil 120A, 120B can be directly formed on each surface 114, 118 of the plurality of layers 110. In embodiments, a finish coat 122 (shown in phantom) can be provided above one of outermost glass layer 120A. In embodiments, the optional finish coat 122 can be patterned to provide access to circuitry 124 through holes in finish coat 122.

IC chip 102 is coupled to copper circuitry 124 bonded to one of outermost E-glass layers 120A (hereinafter “chip-side outermost layer 120A”) on one side. Outermost layers 120A, 120B may have a thickness of approximately 25 to 200 micrometers (μm), with a thickness of approximately 60 to 80 micrometers being preferred, such that they are thin enough that they can be laser drilled for microvias at the dimensions required by the flip chip footprint. Advantageously, the thermo-mechanical characteristics of the E-Glass layers 120A, 120B can be tuned to a value that mitigates fatigue in relation to the expected value of the coefficient of thermal expansion (CTE) of the semiconductor IC 102. For example, some mechanical properties of glass can be tuned or changed by chemical composition or by process. For example, the rate of cooling directly affects the strength of glass. The conventional process of cooling—or annealing—float glass is defined by a slow cooling rate. Increasing the cooling rate of the float glass produces a stronger glass. For example, heat-strengthened glass is cooled at a faster rate than regular annealed glass. Tempered glass, in turn, is cooled at a faster rate than heat strengthened glass. The heat strengthening process does not affect some other properties such as the rate at which glass expands when heated or the stiffness of glass. On the other hand, chemical composition can deliver different glass blends that have various thermo-mechanical properties. For example, Borosilicate glass is a type of glass where the main glass-forming constituents are silica and boron oxide. Borosilicate glass is well known for having very low coefficient of thermal expansion (approximately 5×10⁻⁶/° C. at 20° C.), which is fairly similar to the CTE of many semiconductors. Borosilicate glass is also more resistant to thermal shock than other common glass types.

Boron is used in the manufacture of borosilicate glass in addition to the quartz, sodium carbonate, and calcium carbonate. Typically, the resulting glass composition is about 70% silica, 10% boron oxide, 8% sodium oxide, 8% potassium oxide, and 1% calcium oxide (lime). Borophosphosilicate glass, commonly known as BPSG, is another type of silicate glass that includes additives of both boron and phosphorus. Silicate glasses such as phosphosilicate PSG and borophosphosilicate BPSG are commonly used in semiconductor device fabrication as intermetal layers, e.g., as insulating layers deposited between succeeding higher metal or conducting layers.

Fluorosilicate glass (FSG) is a dielectric used between copper metal layers during the silicon integrated circuit fabrication process. FSG has a low dielectric constant (k) and is now widely adopted by semiconductor foundries for sub 0.30 micron CMOS geometries. Properties of soda-lime glasses report a coefficient of thermal expansion (CTE) of approximately 9 ppm/K between 100 to 300° K. Other glass material, e.g., fused quartz and fused silica glass can contain primarily silica in the amorphous (non-crystalline) form. Fused quartz is a non-crystalline form of silicon dioxide (SiO₂), which is also called silica (the crystalline form of this material is quartz). Fused quartz and fused silica are manufactured using several different processes. The extremely low coefficient of thermal expansion (CTE), about 0.55 ppm/° C. (20-320° C.), accounts for its ability to undergo large and rapid temperature changes without fracturing.

The glass foils 120A, 120B are substantially flatter or more level than industry available pre-impregnated foils of rigid glass cloth materials, commonly referred to as “pre-pregs”. In addition, glass foils 120A, 120B are compatible with several cleaning agents that can be used on E-glass but not on conventional solder mask. In general, a cleaned surface improves adhesion of desired agents, e.g., underfills and therefore the use of E-glass instead of the pre-pregs, provides cleaner chip carrier surfaces.

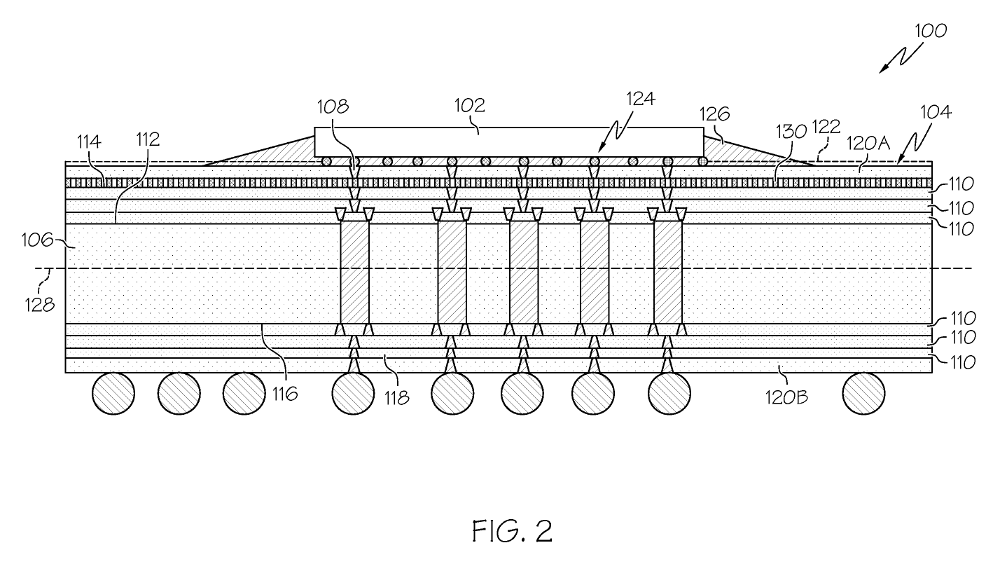

In further illustration, FIG. 2 is a flowchart illustrating a process for manufacturing an IC chip package having outermost E-Glass foils 120A, 120B. In block 210, a glass fiber re-enforced epoxy core 106 is formed using any now known or later developed process. Core 106 may include a commercially available material such as materials available from most printed circuit board reinforced laminate material suppliers. Printed circuit cores generally are made of composite materials, which can include one or more metal layers which can provide stiffness and can conduct electrical signals. Conventional construction of PCB cores is to stack different layers or foils made of electrical-grade glass cloths impregnated with resins one on top of the other. In general, glass cloths are composed of glass yarns woven together in patterns that may differ greatly, in terms of basic characteristics, due to the quality/kind of fibers used either in the warp and/or fill of the cloth. Similarly, there are commercially available non-woven cloths were fibers are simply laid down in layers but not intertwined between warp and fill. The composite uses a resin to fill all gaps between cloth threads, and there are numerous possible combinations and/or types of resins available. The most common is the type that uses the epoxy moieties based complexes, which are generally indicated by the number of links the base moiety has to form the long polymer chain via bi-functional, tetra-functional or multifunctional epoxies. In the recent years, other compounds have became available that are specifically used to address more complex and demanding functions such as the one required for semiconductor carriers. Within these new resins complexes, there is a class of aromatic polyester polymers also known as liquid crystal polymers (LCPs), benzocyclobutene (BCB), annylated poly (phenylether) (APPE), bismaleimide triazine (BT) the latter tied to older cyanate ester materials used in the PCB processes.

Cores also can be made of non-electrically conductive materials, which have a minimum rigidity to support the application or deposition of additional layers on one or either sides of the core structure. These structures also can be made by materials which are inherently flexible such as films of poly (4,4′-oxydiphenylene-pyromellitimide) commercially known as Kapton® produced from the condensation of pyromellitic dianhydride and 4,4′-oxydiphenylamine. Alternatively, the core 106 can be made of other polyamides e.g., any of various combinations of biphenyltetracarboxylic acid dianhydride (BPDA), pyrometallic acid dianhydride (PDA), paraphenylenediamine (PPD), oxydianiline (ODA) and their derivatives. In embodiments, other constructive techniques are based on thermoplastic materials that include blends or composition of derivatives from polytetrafluoroethylene (PTFE) such as Teflon®, poly-tetrafluoroethylene-co-perfloropropyl-vinyl-ether (PFA) and other formulations. Central core 106 can also accept combinations of metals and or composite structures, which may use different metal structures such as foils of copper, copper-invar-copper jacketed in between dielectric layers, aluminum and/or the like.

In block 220, a plurality of copper circuitry 108 containing, particle re-enforced epoxy layers 110 are then formed symmetrically to each surface 112, 116 of core 106. This process may also include using any now known or later developed process such as sequential lamination, co-lamination, with metallurgy deposited by semi-additive plating, circuitized by a subtractive process, or formed by a dual damascene process. Layers 110 may include a material such as Resin Coated Copper Foil® (RCC or RCF) which can be made of a copper foil and a layer of semi-cured (B-stage) resin. Alternatively, the layer 110 can be built by applying layers of resin onto a pre-existing PCB and then plating copper on top of the newly created dielectric layer. These resin layers typically use chemistries similar to the one used for regular PCB such as epoxy compounds or blends, APPE, BT, and other polymers. In embodiments, the resins also can be loaded with fine silica, e.g. SiO2, or aluminum oxide Al2O3 particles or other powders/compounds, to enhance specific characteristics such as CTE, thermal properties and/or to enhance the compatibility to the manufacturing processes. In block 230, outermost glass layers or foils 120A, 120B can be formed on a substrate, which is separate from the semi-finished organic substrate 104 formed by core 106 and layers 110. Glass layers or foils 120A, 120B can include any commercial Glass materials. In embodiments, the glass layers or foils 120A, 120B can be one of a chemical resistant glass (C-Glass), high-alkali glass (A-Glass), electrical grade glass (E-Glass), high-strength glass (S-Glass) and dielectric constant glass (D-Glass). In embodiments, E-glass can have a composition essentially based on silica, alumina, lime and boric anhydride, the boric anhydride, present in amounts ranging in practice from 5 to 13% in the compositions of glasses termed “E-glass”, replacing part of the silica, the E-glass foil being furthermore characterized by a limited content of alkali metal oxides (essentially Na₂O and/or K₂O). Besides common silica-based glasses, there are also non silica based glass using many other inorganic and organic materials, including plastics (e.g., acrylic glass), carbon, metals, carbon dioxide, phosphates, borates, chalcogenides, fluorides, germanates (glasses based on GeO₂), tellurites (glasses based on TeO₂), antimonates (glasses based on Sb₂O₃), arsenates (glasses based on As₂O₃), titanates (glasses based on TiO₂), tantalates (glasses based on Ta₂O₅), nitrates, carbonates and many other substances each one of them may not include silica as a major constituent and that may have physical-chemical properties useful for applications enabled by the presented embodiments of this invention or derivative enabling other specialized technical applications such as optical applications using fluorozirconate, fluoroaluminate, aluminosilicate, phosphate and chalcogenide glasses.

In block 240, the E-Glass layers or foils 120A, 120B can be perforated with a desired pattern prior to being joined with the semi-finished chip carrier formed by core 106 and layers 110. In block 250, outermost layer(s) 120A, 120B can be laminated to layers 110 using pressure and thermal curing. Alternatively, outermost layer(s) 120A, 120B can be bonded to layers 110 using pressure, heat and an adhesive layer 130. Regardless of the extended range of polymers, copolymers and polymer blends/products made available from the industry to join composite layers, the primary role is still the one occupied by epoxies, modified epoxies and resins complexes (adhesive layer 130) used for the construction of build-up layers in High Density Interconnect (HDI) packages. In the embodiments, the joining material is a B-stage layer of the same dielectric composing the underlying stacks of layers composing the substrate. The B-stage layer is ideal for additional processing steps which may include laser drilling, of the gluing dielectric, with the same process parameters and final characteristics of the process used in building the underneath layers. In embodiments, adhesive materials may include acrylics customarily used for gluing polyimides and other materials such as perfluoroethylenepropylene or polyimidesiloxane for high temperatures. Other materials such as polyurethanes have shown some thermal or functional limitations. Advantageously, the semi-finished organic substrates 104 can be fully tested prior to being joined to the lamination of glass layers or foils 120A, 120B on top of the substrate 104.

In embodiments, outermost glass layers 120A, 120B can be directly formed on a surface (114, 118 as shown) of layers 110. In block 260, a laser can be used to ablate or to “clean” an opening of the E-Glass foils 120A, 120B to expose the bottom circuit of the substrate 104. In block 270, connections for the chip carrier can be established by use of conventional plating operations, e.g., palladium (Pd) colloidal seeding, copper (Cu) electroplating and pattern etching. Chip connections can occur directly on the glass opening to serve as the mounting pads on the substrate for the IC chip 102. Then, IC chip 102 may be coupled to copper circuitry bonded to chip-side outermost layer 120A in a conventional manner, e.g., via ball grid array 140 and epoxy 142. In block 280, the resulting IC chip packages 100 can be diced to singulate the individual IC chip packages 100.

In a further embodiment in the block 240 the E-Glass layers or foils 120A, 120B can be perforated with a desired pattern and prior to being joined with the semi-finished chip carrier formed by core 106 and layers 110, the holes are filled with a conductive paste made of electrically conductive particles loaded into a supporting resin matrix. In block 250, outermost layer(s) 120A, 120B can be laminated to layers 110 using pressure and thermal curing which will assure in sequence: 1) the joining of the conductive paste to existing patterns of connecting pads onto the surface of the multi-layer PCB circuit and 2) the sintering or polymerization of the conductive media placed into the formed glass holes which will freeze the conductive particles to maintain the newly formed electrical paths.

In other embodiments, the amorphous E-Glass section can be applied to a portion of the substrate surface hosting the large semiconductor device. This amorphous E-Glass section can be connected by beams to an outer frame still attached to the same laminate in the empty slots that are exposing areas of the underneath laminate, where discrete components can be mounted. Reducing the area covered by the E-Glass foil will decouple the CTE issue related to large areas between the laminate and the E-Glass, while the E-Glass addresses the CTE issues with respect to large semiconductors. In addition to the concept of having sections of glass mated to substrate, there is the possibility of using more than one glass island to host a plurality of devices. The glass sections host only vertical transitions from the silicon down to the organic substrate. Areas of the substrate not covered by the amorphous glass can be used to mount different SMT devices, for example EEPROMS, discrete components, power regulators, to increase the possibility of integrating more and more functions into a System on Package approach.

In embodiments, transparent glass layers 120A, 120B can be used to manage injection of optical signals into the “core” of the electronic package. For example, the application of a suitable layer of optical glass on the top side of the substrate can enable the mounting of a vertical cavity surface emitting laser (VCSEL) as a component which may inject a laser beam into the glass layer to reach mirrors embedded within the underneath chip carrier. The use of a glass layer with acceptable optical properties can avoid the exposure of embedded mirrors and related niches/cavities to the external environmental dust/pollution driven by other industrial processes required to produce regular electronic assemblies and/or to drive expensive infrastructures to control particle/dust contamination over the surfaces generating the optical path for light. The mating of the glass foil to the substrate is possible with compatible polymers, which have the right optical properties. A similar embodiment can be constructed by allocating a stand alone or IC embedded receiver/optical device such as a photodetector/photodiode.

Along with the concept of sections of glass mated to the substrate 104 is the possibility of using more than one glass island to host a plurality of devices. The glass sections can host vertical transitions from the silicon down to the organic substrate. Areas of the substrate not covered by the amorphous glass can be used to mount different surface mount technology (SMT) devices, e.g., EEPROMS, discrete components and power regulators, to increase the possibility of integrating more and more functions into a “System on Package” approach.

The method and structure as described above are used in the fabrication of packaged integrated circuit chips. The resulting packaged integrated circuit chips can be distributed by the fabricator in panel form (that is, as a single substrate panel that has multiple unpackaged chips), a as a single substrate mounted bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims, which are to be accorded with the broadest interpretation so as to encompass all such modifications and similar structures.

We claim:

1. An integrated circuit (IC) chip package comprising:
an IC chip; and
a substrate coupled to the IC chip, the substrate comprising:
a glass fiber re-enforced epoxy core, a plurality copper circuitry containing particle re-enforced epoxy layers symmetrically-oriented to each surface of the glass fiber re-enforced epoxy core, and an outermost amorphous glass layer on each surface of the plurality of layers,
wherein the IC chip is coupled to copper circuitry bonded to one of the outermost amorphous glass layers.

2. The chip package of claim 1, wherein the glass layer is one of chemical resistant glass (C-Glass), high-alkali glass (A-Glass), electrical grade glass (E-Glass), high-strength glass (S-Glass) and dielectric constant glass (D-Glass).

3. The chip package of claim 1, wherein the glass layer is optical glass.

4. The chip package of claim 1, further comprising an optical device.

5. The chip package of claim 4, wherein the optical device is a vertical cavity surface emitting laser (VCSEL) mounted on a top surface of the optical glass.

6. The chip package of claim 4, wherein the optical device is photodetector mounted on a top surface of the optical glass.

7. The chip package of claim 1, wherein a coefficient of thermal expansion (CTE) of the outermost amorphous glass layer is tuned to match the CTE of the IC chip.

8. The chip package of claim 1, further comprising an opening in the outermost amorphous glass layer, the opening for exposing an underneath circuit of the substrate.

9. The chip package of claim 1, wherein a coefficient of thermal expansion (CTE) of the outermost amorphous glass layer is tuned to approximately 8 to 18 parts per million per degree Celsius (ppm/° C.).

10. The chip package of claim 9, further comprising an adhesive layer between the outermost amorphous glass layer and the plurality of layers.

11. A method for manufacturing integrated circuit (IC) chip packages, the method comprising:
forming a glass fiber re-enforced epoxy core;
forming a plurality copper circuitry containing, a plurality of particle re-enforced epoxy layers symmetrically-oriented to each surface of the glass fiber re-enforced epoxy core;
forming an outermost amorphous glass layer on each surface of the plurality of layers; and,
mounting an IC chip to copper circuitry bonded to one of the outermost amorphous glass layers.

12. The method of claim 11, wherein forming an outermost amorphous glass layer includes selecting a glass from the group of consisting of chemical resistant glass (C-Glass), high-alkali glass (A-Glass), electrical grade glass (E-Glass), high-strength glass (S-Glass) and dielectric constant glass (D-Glass).

13. The method of claim 11, wherein forming an outermost amorphous glass layer includes selecting an optical glass.

14. The method of claim 13, further comprising mounting an optical device on a top surface of the optical glass.

15. The method of claim 14, wherein the mounting an optical device on a top surface of the optical glass includes mounting a vertical cavity surface emitting laser (VCSEL) on the top surface of the optical glass.

16. The method of claim 11, wherein forming an outermost amorphous glass layer includes laminating the outermost layer to the plurality of layers using pressure and thermal curing.

17. The method of claim 11, wherein forming an outermost amorphous glass layer includes pre-curing the outermost layer and bonding the outermost layer to the plurality of layers using pressure, heat and an adhesive layer.

18. The method of claim 11, wherein forming an outermost amorphous glass layer includes pre-curing the outermost amorphous glass layer and perforating the outermost amorphous glass layer with a desired connection pattern.

19. The method of claim 14, further comprising ablating an opening in the outermost amorphous glass layer.

20. The method of claim 19, further comprising filling the opening with a conductive paste prior to lamination.
